(19) United States
(12) Patent Application Publication
(10) Pub. No.: US 2011/0024738 A1
(43) Pub. Date: Feb. 3, 2011

(54) SUBSTRATE HAVING IMPRINTED STRUCTURE

(75) Inventors: Wolfgang Lohwasser, Gailingen (DE); Michael Kiy, Winterthur (CH); Matthias Reinhold, Neuhausen (CH); Christian Weber, Gailingen (DE)

Correspondence Address: RATNERPRESTIA, P.O. BOX 980, VALLEY FORGE, PA, 19482, US

(73) Assignee: Amcor Flexibles Kreuzlingen Ltd., Kreuzlingen (CH)

(21) Appl. No.: 12/936,736

(22) PCT Filed: Apr. 2, 2009
(86) PCT No.: PCT/EP2009/002391

§ 371 Date: Oct. 7, 2010

(30) Foreign Application Priority Data
Apr. 8, 2008 (EP) 08405100.2

(51) Int. Cl. H01L 51/50; H05K 1/09

(52) U.S. Cl. 257/40; 174/257; 438/46; 257/E51.018

(57) ABSTRACT

In a substrate with a hydrophilic surface and a structure made of a conductive and/or light-emitting organic polymer imprinted on the hydrophilic surface, the hydrophilic surface is formed from a layer arranged on the substrate of an oxide ceramic and/or metallic material.

The invention relates to a substrate with a hydrophilic surface and a structure made of a conductive and/or light-emitting organic polymer imprinted on the hydrophilic surface.

Conductive and light-emitting organic polymers can be applied relatively easily and economically to a substrate by suitable printing techniques. In particular, during the production of microelectronic components, it has to be possible for the conductive material to be imprinted on the substrate in accordance with the circuit logic to be achieved as a structure with high spatial resolution. The same applies during the production of colour displays and organic light-emitting diodes (OLEDs) to the light-emitting polymer.

A method for producing a structure from a conductive organic polymer on a substrate by means of gravure printing is known from DE-A-102 40 105. The structured print stamp has a hydrophobic surface and the substrate has a hydrophilic surface, and the print solution is hydrophilic. The substrate is manufactured from an oxidic material, such as, for example, glass or ceramic, or from a metal, such as, for example, copper or nickel. Further materials suitable for producing the substrate are polymers, which contain hydroxyl groups, such as, for example, polyvinylpyrrolidone, or else polymers which are retrospectively functionalised with hydroxyl groups, for example by a treatment in oxygen plasma.

It is known from DE-A-102 36 404, in a substrate for imprinting a conductive or light-emitting polymer by means of inkjet printing, in order to achieve a high spatial resolution, to subject the regions which are to be imprinted with the polymer to a UV-ozone or an oxygen plasma treatment.

The drawbacks of plasma and corona treatments of plastics material surfaces to adapt the surface tension are an impermanent stability and an unsatisfactory reproducibility of the surfaces which are treated in this manner.

The present invention is based on the object of providing a substrate of the type mentioned at the outset with a reproducible and permanently stable hydrophilic surface. A further aim of the invention is the provision of a flexible substrate of the type mentioned at the outset which is based on a plastics material film.

The fact that the hydrophilic surface is formed by a layer arranged on the substrate which is made of an oxide ceramic and/or metallic material leads to the achievement of the object according to the invention.

A coating with an oxide ceramic material, apart from providing a hydrophilic surface, has the further advantage that it additionally acts as a barrier against the passage of water vapour and the substrates coated with an oxide ceramic material are therefore particularly suitable for water-sensitive components, such as are used in polymer electronics, for example in the form of polymer circuits, polymer solar cells or polymer light-emitting diodes.

The layer which is arranged on the substrate preferably contains a compound of formula SiOₓ or consists completely of SiOₓ, x being a number from 0.9 to 2.0, preferably a number between 1.5 and 1.8.

The oxide ceramic layer may be produced by methods of thin-layer vacuum technology, in particular based on electron beam evaporation or resistance heating or inductive heating of materials to be evaporated, known, for example, as vapour deposition materials, target materials or targets. Electron beam evaporation is preferred. The described methods can be carried out reactively and/or with ion support. These methods are carried out in such a way that, in the vacuum, the materials to be evaporated made of, for example, mixtures of silicon dioxide (SiO₂) with metallic silicon, as the materials to be evaporated, are evaporated in the vacuum of a vacuum chamber. In the vacuum chamber, a ceramic layer made of or containing the compounds of formula SiOₓ is deposited over the whole area on the substrate and forms the oxide ceramic layer.

Further additives, such as Al₂O₃, B₂O₃ and/or MgO in quantities of, for example 5 to 30 mol %, in each case based on the SiO₂, can be added to the SiO₂ as the materials to be evaporated. Al, B and/or Mg, as further additives in pure form or as a Si alloy, Can also be added to the SiO₂, as materials to be evaporated. The additions of Al, B and/or Mg can be added in quantities of, for example, 5 mol % to 30 mol % in each case based on the Si, The quantity ratios of the oxygen-containing compounds, such as SiO₂, Al₂O₃, B₂O₃ and MgO, to the metals or semi-metals are, for example, selected in such a way that an oxygen deficiency of 10 to 30%, based on the sum of the pure oxides in the evaporated material, is stoichiometrically produced.

The coating method is controlled by means of the evaporation rate of the crucible material, the deposition rate on the substrate and the exposure period of the substrate in the vacuum chamber atmosphere in such a way that the layer of oxide ceramic material which is deposited on the substrate has a thickness of 50 nm (nanometres) to 2000 nm, preferably 100 to 1000 nm, in particular 150 to 500 nm.

The layer of metal which is arranged on the substrate consists, for example of chromium, aluminium, nickel, titanium, iron, molybdenum or an alloy composed of at least two of these metals. Preferred metals are chromium and aluminium, chromium being particularly preferred. A preferred alloy is V2A steel.

It has surprisingly been shown that a monoatomic metal layer is already adequate for a substrate surface with good hydrophilic properties. Monoatomic does not mean here that the atoms have to be arranged in a monoatomic layer. Rather, as in all condensation processes, clusters of atoms form. A monoatomic layer is taken to mean here a surface coating which would lead to a virtually monoatomic layer if the atoms were to be distributed uniformly over the substrate surface.

Although thicker metal layers may also be used, for cost reasons and to ensure a high optical transparency, a thickness of a maximum of 5 nm, in particular a layer thickness of 0.1 to 0.5 nm corresponding to a monoatomic coating, is preferred.

The small layer thicknesses are completely sufficient to change the surface properties of the substrate. The optical transparency and the insulation properties of the coated substrate are virtually unchanged.

The substrate may also be equipped with a first layer made of oxide ceramic material and a second layer of metal arranged on the first layer, or be equipped with a first layer made of metal and a second layer made of oxide ceramic material arranged on the first layer.

Preferred is a first layer of SiOₓ with a thickness of 50 to 2000 nm, preferably 100 to 1000 nm, in particular 150 to 500 nm, and a second layer of metal arranged on the first layer made of SiOₓ with a thickness of a maximum of 5 nm, preferably a layer thickness of 0.1 to 0.5 nm corresponding to a monoatomic coating.

The metal layer may be applied, for example, by a further thin-layer vacuum method, as described above, with one of the metals mentioned as the material to be evaporated, or preferably by sputtering with one of the metals mentioned as the target. In continuous coating processes, the substrate may firstly be provided in a first chamber with the oxide ceramic layer, then guided through a split sluice and provided with the metal layer in a further chamber by sputtering.

Plastics material films, in particular made of a polyester, preferably made of a polyethylene terephthalate (PET), of oriented polyamide (oPA) or of oriented polypropylene (oPP) are the preferred substrate. The substrate may also be a multi-layer film, at least the film surface to be imprinted being a layer of plastics material.

The metal layer may be deposited in line with the oxide ceramic material to be applied by the thin-layer vacuum method. As a very thin metal layer is already sufficient to achieve the required surface properties, it is possible to sputter this layer with a sputter cathode at very high band speeds, which are compatible with the vapour deposition process.

Owing to the small layer thickness required of the metal layer it is possible for a coating source, for example a sputter cathode, to be arranged between two guide rollers without a coating roller (free span operation).

The conductive polymers which are imprinted on the substrate can be used in polymer circuits, such as polymer transistors, transparent conductive layers in solar cells, light-emitting diodes and as a resistor, for example in sensors. Further application possibilities are anti-static coatings. The combination with SiOₓ additionally has a barrier effect against water vapour and is, therefore, particularly suitable for water-sensitive components, such as are used in polymer electronics as polymer circuits, polymer solar cells and polymer light-emitting diodes.

The imprinting of the structure made of the conductive and/or light-emitting polymer can be carried out with all the current printing methods, for example offset, gravure, screen, flexo or inkjet methods.

The polymers are applied in the form of aqueous dispersions and then dried. Suitable conductive polymers are, for example 3,4-polyethylenedioxythiophene/polystyrene sulfonate (PEDOT:PSS, Baytron®) or polyaniline. Suitable light-emitting polymers are, for example, polymers from the family of polyphenylene vinylenes (PPVs) or of polyfluorenes.

Further advantages, features and details of the invention emerge from the following description of preferred embodiments and with the aid of the drawings, in which, schematically:

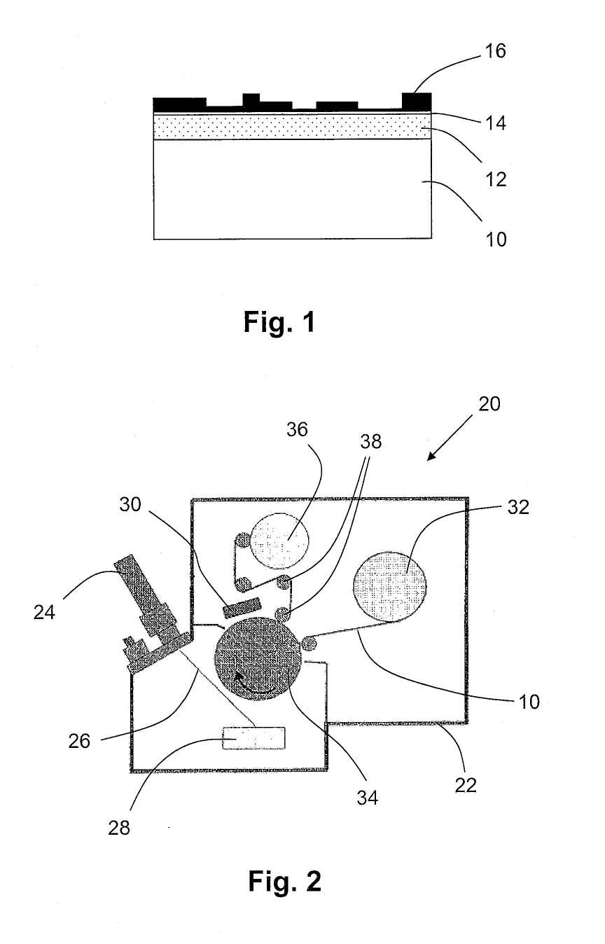

FIG. 1 shows the structure of a coated substrate;

FIG. 2 shows a device for producing the coated substrate of FIG. 1.

A substrate 10 made of a plastics material film, which is 12 μm thick, for example, made of PET, is coated with a ceramic layer 12, which is 80 nm thick, for example, made of SiOₓ, x being 1.8, for example, by vapour deposition in a vacuum. A metal layer 14 which is made of chromium applied by sputtering in a vacuum and 0.2 nm in thickness, for example, is arranged on the ceramic layer 12. The metal layer 14 is imprinted with a conductive structure 16 applied by means of gravure printing, made of a conductive polymer, for example of 3,4-polyethylenedioxythiophene/polystyrene sulfonate (PEDOT:PSS, Baytron®).

A coating system 20 shown in FIG. 2 has a vacuum chamber 22. An electron beam 26 emitted by an electron beam cannon 24 is guided to the material 28 which is present in a crucible or in a plate, the material 28 being heated to produce the ceramic layer 14 by the energy of the impinging electron beam 26 and evaporated.

In the vacuum chamber, a metal or the alloy required to form the thin metal layer is also soldered on in the form of a metal plate on a sputter cathode 30. In the vacuum chamber 22, an argon atmosphere is maintained at a pressure of 3.10⁻³ mbar, The electric power for the sputter cathode is adjusted in accordance with the desired layer thickness.

Within the vacuum chamber 22, the substrate film 10 is unrolled from the first roll 32 and drawn over a roller 34. The substrate film 10 lying on the roller 34 as the substrate carrier, in the working region, forms a substrate face, on which the material 28 evaporated by the electron beam 26 of the electron beam cannon 24 is deposited in the form of the ceramic layer 12. The thin metal layer 14 is applied by sputtering to the ceramic layer 12 which is deposited on the substrate film 10. Once the coating with the ceramic layer 12 and the metal layer 14 has taken place, the substrate film 10 coated in this manner is wound onto a further roll 36. Guide rollers 38 are provided to guide the substrate film 10. The band speed of the substrate film 10 in the vacuum chamber 22 is, for example, about 400 m/min. The substrate film 10 which is wound onto the roll 36 and coated with the ceramic layer 12 and the metal layer 14 is then—not shown in the drawing for reasons of better clarity—provided with the structure of the conductive polymer in a printing machine.

### Example 1

A film, which is 12 μm thick, made of polyethylene terephthalate (PET) and being used as the substrate, is firstly pretreated in line by means of an oxygen plasma, then coated in the vacuum by means of electron beam vapour deposition with 80 nm SiO_{1.8}. A coating with chromium then follows. The band speed is 200 m/min and the coating width is 690 mm. The coating with chromium takes place on the same coating roller, on which the SiO_{1.8} coating is also carried out, by means of a DC magnetron sputter cathode (PK750 from Leybold), on which a chromium plate is soldered as the target. The deposition takes place in an argon atmosphere at 3.10⁻³ mbar. The electric power for the sputter cathode is 10 kW. A layer thickness of about 1.5 angstrom (0.15 nm) is produced under these conditions.

Microelectronic components were imprinted on a substrate, which is coated in a vacuum as described above, in a printing machine by means of gravure printing with an aqueous dispersion of 3,4-polyethylenedioxythiophene/polystyrene sulfonate (PEDOT:PSS, Baytron® FE) and then dried in a warm air flow. The imprinted components exhibited a high spatial resolution.

1. A substrate with a hydrophilic surface and a structure made of a conductive and/or light-emitting organic polymer imprinted on the hydrophilic surface, wherein the hydrophilic surface is formed by a layer which is arranged on the substrate and made of an oxide ceramic and/or metallic material.

2. A substrate according to claim 1, wherein the layer which is arranged on the substrate comprises a compound of formula SiOₓ, x being a number from 0.9 to 2.0.

3. A substrate according to claim 2, wherein the layer which is arranged on the substrate is made of oxide ceramic material and has a thickness of 50 to 2000 nm.

4. A substrate according to claim 1, wherein the layer, which is arranged on the substrate, consists of metal.

5. A substrate according to claim 4, wherein the layer has a thickness of a maximum of 5 nm.

6. A substrate according to claim 1, wherein arranged on the substrate is a first layer of SiOₓ with a thickness of 500 to 2000 nm, and arranged on the first layer of SiOₓ is a second layer made of metal with a thickness of a maximum of 5 nm.

7. A substrate according to claim 1 wherein the substrate has a plastic material film.

8. A method for producing a substrate with a hydrophilic surface and a structure made of a conductive and/or organic polymer imprinted on the hydrophilic surface, wherein a substrate is coated with an oxide ceramic and/or metallic material to provide a coated substrate and the coated substrate is printed with an aqueous dispersion of a conductive and/or light-emitting organic polymer.

9. A method according to claim 8, wherein the substrate is coated with SiOₓ, x being a number from 0.9 to 2.0.

10. A method according to claim 8, wherein the substrate is coated with metal.

11. A method according to claims 8, wherein the substrate is coated with SiOₓ, x being a number from 0.9 to 2.0, and the substrate coated with SiOₓ then being coated with metal.

12. A method according to claim 8, wherein the metal is deposited in line with the oxide ceramic material on the substrate.

13. A substrate according to claim 2, wherein x is a number between 1.5 and 1.8.

14. A substrate according to claim 3, wherein the layer has a thickness of 150 to 500 nm.

15. A substrate according to claim 1, wherein the layer, which is arranged on the substrate consists of a metal selected from chromium, aluminum, nickel, titanium, iron, or molybdenum or an alloy composed of at least two of these metals.

16. A substrate according to claim 1, wherein the layer, which is arranged on the substrate, consists of metal and has a thickness of 0.1 to 0.5 nm corresponding to a monoatomic coating.

17. A substrate according to claim 3, wherein arranged on the substrate is a first layer of SiOₓ with a thickness of 150 to 500 nm, and arranged on the first layer of SiOₓ is a second layer made of metal with a thickness of 0.1 to 0.5 nm corresponding to a monoatomic coating.

18. A substrate according to claim 1, wherein the substrate has a plastics material film made of a plastic selected from polyesters, oriented polyamides, or oriented polypropylene.

19. A method according to claim 11, wherein the metal is chromium.

20. A method according to claim 11, wherein x is a number between 1.5 and 1.8.
